(19) United States
(12) Patent Application Publication
(10) Pub. No.: US 2011/0199316 A1
(43) Pub. Date: Aug. 18, 2011

(54) SENSOR STRUCTURE AND TOUCH DISPLAY PANEL

(75) Inventors: Tsung-Chin Cheng, Kaohsiung City (TW); Yue-Hung Wu, Chiayi City (TW); Zeng-De Chen, Yunlin County (TW); Seok-Lyul Lee, Hsinchu City (TW)

(73) Assignee: AU OPTRONICS CORPORATION, Hsinchu (TW)

(21) Appl. No.: 12/775,482

(22) Filed: May 7, 2010

(30) Foreign Application Priority Data
Feb. 12, 2010 (TW) 99104814

(51) Int. Cl. G06F 3/041; G01R 27/08

(52) U.S. Cl. 345/173; 324/691

(57) ABSTRACT

A touch display panel including a first substrate and a second substrate is provided. A plurality of sensing units is disposed on the first substrate, and each sensing unit includes a main-sensing pattern and at least one sub-sensing pattern. The at least one sub-sensing pattern is electrically connected to the main-sensing pattern, and the size of the at least one sub-sensing pattern is smaller than the size of the main-sensing pattern. A plurality of sensing electrodes is disposed on the second substrate, and each of the sensing electrodes is disposed corresponding to one of the sensing units on the first substrate.

### CROSS-REFERENCE TO RELATED APPLICATION

This application claims the priority benefit of Taiwan application serial no. 99104814, filed on Feb. 12, 2010. The entirety the above-mentioned patent application is hereby incorporated by reference herein and made a part of specification.

### BACKGROUND OF THE INVENTION

1. Field of the Invention

The invention generally relates to a sensor structure, and more particularly, to a resistive sensor structure and a touch display panel having this resistive sensor structure.

2. Description of Related Art

Generally, touch display panels can be roughly categorized as capacitive type, resistive type, and photosensitive type based on the design of touch sensing modes. In addition, touch display panels can be categorized as added type and integrated type according to their structures. In the integrated type resistive touch panels, a plurality of touch conductors is formed on an opposite substrate and a photo spacer, and a plurality of touch pads is formed on an active device array substrate. When the user presses the opposite substrate, the touch conductors on the photo spacer conduct the touch pads on the active device array substrate to locate the position pressed by the user. In this case, the gap between the touch conductor and the touch pad affects the sensibility of the touch panel.

In addition, an alignment layer is usually disposed on the touch conductors of the opposite substrate and the touch pads of the active device array substrate for controlling a rotation angle of liquid crystals. As the alignment layer mostly adopts insulating material, a thickness of the alignment layer also affects the sensibility of the touch panel. For example, when a thicker alignment layer is remained on the touch conductors and the touch pads, an active force for touch sensing becomes larger, such that the sensibility of the touch panel decreases.

### SUMMARY OF THE INVENTION

The invention provides a touch display panel having favorable sensibility.

The invention further provides a sensor structure having favorable sensibility.

A touch display panel including a first substrate and a second substrate is provided. A plurality of sensing units is disposed on the first substrate, where each sensing unit includes a main-sensing pattern and at least one sub-sensing pattern. The at least one sub-sensing pattern is electrically connected to the main-sensing pattern and the size of the at least one sub-sensing pattern is smaller than that of the main-sensing pattern. A plurality of sensing electrodes is disposed on the second substrate, where each sensing electrode is disposed corresponding to one of the sensing units on the first substrate.

A sensor structure including a plurality of main-sensing patterns, a plurality of sub-sensing patterns, and a sensing electrode is further provided. At least one of the sub-sensing patterns is electrically connected to at least one of the main-sensing patterns. Moreover, the size of the at least one sub-sensing pattern is smaller than that of the at least one main-sensing pattern. The sensing electrode is disposed opposite to the main-sensing patterns and the sub-sensing patterns.

Accordingly, the sensor structure of the invention includes main-sensing patterns and sub-sensing patterns with different sizes. Main-sensing patterns and sub-sensing patterns compensate each other and thus enhance sensibility of the sensor structure, so that the touch display panel has an uniform active force for touch sensing.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view showing a touch display panel according to an embodiment of the invention.

FIG. 2 is a schematic cross-sectional view taken along lines I-I′, II-II′, and III-III′ in FIG. 1.

### DESCRIPTION OF EMBODIMENTS

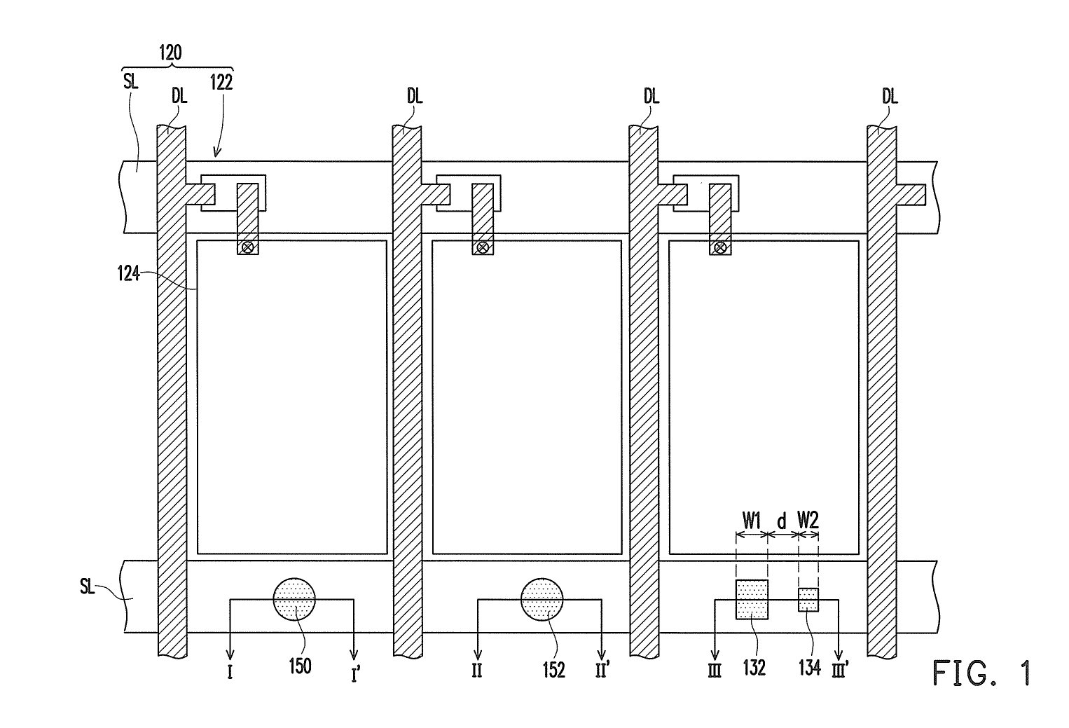

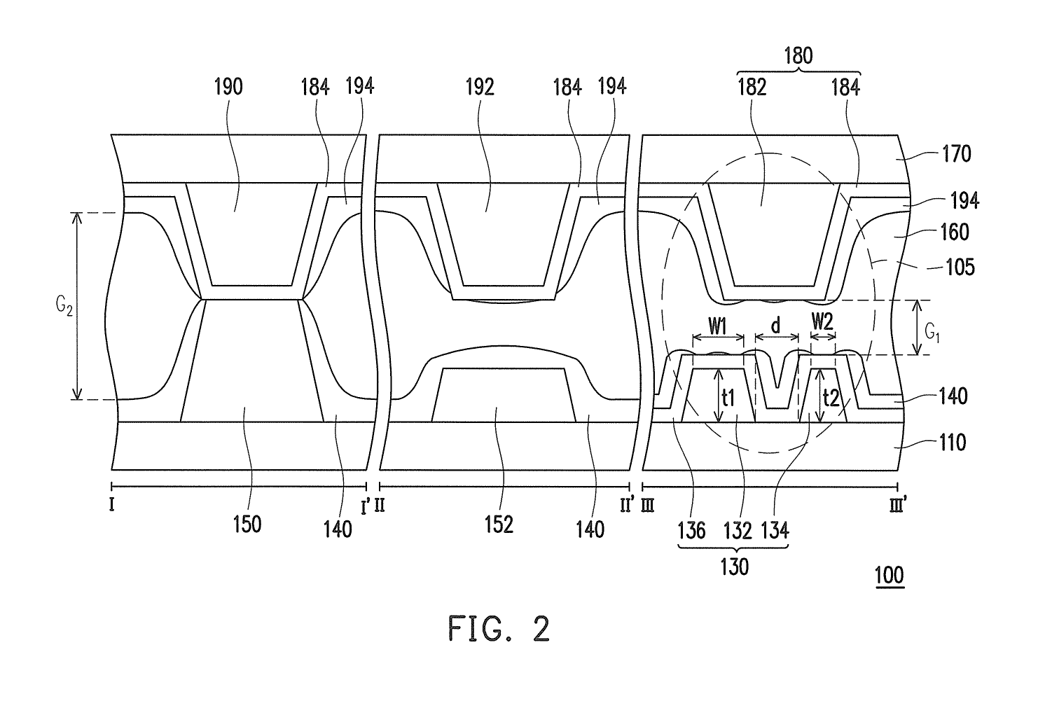

FIG. 1 is a schematic top view showing a touch display panel according to an embodiment of the invention. FIG. 2 is a schematic cross-sectional view taken along lines and in FIG. 1. For better illustration, FIG. 1 merely shows the schematic top view of a first substrate of a touch display panel in the present embodiment and omits a second substrate. Referring to FIG. 1 and FIG. 2, a touch display panel 100 of the present embodiment is an integrated touch display panel, for example, and includes a first substrate 110, a second substrate 170, and a display medium 160 sandwiched between the two substrates 110, 170. In addition, the display medium 160 includes liquid crystal molecules or other display media.

In the present embodiment, the first substrate 110 is, for example, an active device array substrate, in which an active device array layer 120 and a plurality of sensing units 130 are disposed thereon. The active device array layer 120 includes scan lines SL, data lines DL, and active devices 122 disposed on the first substrate 110. Here, the active devices 122 are electrically connected to the scan lines SL and the data lines DL. Each active device 122 is a thin film transistor (TFT), for example, and includes a gate, a source, a channel, and a drain. In the present embodiment, a pixel electrode 124 is further disposed on the active device array layer 120. Each sensing unit 130 includes a main-sensing pattern 132, at least one sub-sensing pattern 134, and an electrode layer 136 covering on the main-sensing pattern 132 and the sub-sensing pattern 134. The size of the sub-sensing pattern 134 is smaller than the size of the main-sensing pattern 132. Herein, the size refers to volume, thickness, width, minimum horizontal cross-sectional area, minimum vertical cross-sectional area, width of a long side, or width of a short side, for example. For instance, a thickness t2 of the sub-sensing pattern 134 substantially equals to a thickness t1 of the main-sensing pattern 132. However, a width w2 of a short side of the sub-sensing pattern 134 is about 0.1 to about 1.0 μm smaller than a width w1 of a short side of the main-sensing pattern 132, for example. In details, if the main-sensing pattern 132 and the sub-sensing pattern 134 are rectangles, they each have a long side and a short side. For example, the width w2 of the short side of the sub-sensing pattern 134 is about 0.1 to about 1.0 μm smaller than the width w1 of the short side of the main-sensing pattern 132 favorably. If the main-sensing pattern 132 and the sub-sensing pattern 134 are squares, the side width w2 of the sub-sensing pattern 134 is about 0.1 to about 1.0 μm smaller than the side width w1 of the main-sensing pattern 132 favorably. Obviously, the invention does not limit the main-sensing pattern 132 and the sub-sensing pattern 134 to have the same or different shapes. That is, the shapes of the main-sensing pattern 132 and the sub-sensing pattern 134 can be, for example, polygonal, circular, or irregular.

As shown in FIG. 2, a distance d between the sub-sensing pattern 134 and the main-sensing pattern 132 ranges, for example, from about 2.0 to about 20 μm. Further, the main-sensing pattern 132 is electrically connected to the sub-sensing pattern 134 through the electrode layer 136, for example. The main-sensing pattern 132 and the sub-sensing pattern 134 are fabricated using, for example, conductive material, such as Metal 1 for forming the gate and the scan lines SL, semiconductive material for forming the channel of the active device 122, or Metal 2 for forming the source, the drain, and the data lines DL. The electrode layer 136 is, for example, fabricated using transparent conductive material such as indium tin oxide (ITO). Additionally, even though the main-sensing pattern 132 and the sub-sensing pattern 134 are represented as single-layered structures in FIG. 2, the main-sensing pattern 132 and the sub-sensing pattern 134 can also be stacked patterns. For example, the main-sensing pattern 132 and the sub-sensing pattern 134 can be stacked by a gate layer, a gate insulation layer, a semiconductor layer, a source layer, and a passivation layer which are formed in the fabrication of the active device 122.

The touch display panel 100 of the present embodiment further includes an alignment layer 140 disposed on the first substrate 110 and covers the sensing units 130. The alignment layer 140 exposes at least one of the main-sensing pattern 132 and the sub-sensing pattern 134 of each sensing unit 130. In the present embodiment, since the main-sensing pattern 132 and the sub-sensing pattern 134 are covered by the electrode layer 136, the alignment layer 140 thus covers the electrode layer 136 and at least exposes a portion of the electrode layer 136. The alignment layer 140 is fabricated using polyimide (PI) or other suitable alignment materials, for instance, and is fabricated by performing printing process and re-flowing process, for example.

In the present embodiment, a plurality of main-stacked layer 150 and a plurality of sub-stacked layer 152 are further disposed on the first substrate 110. Each of the main-stacked layer 150 and the sub-stacked layer 152 is stacked by the gate layer, the gate insulation layer, the semiconductor layer, the source layer, and the passivation layer formed in the fabrication of the active device 122, for example. Moreover, the main-stacked layers 150 and the sub-stacked layers 152 are also covered by the alignment layer 140.

Referring to FIG. 2, the second substrate 170 is disposed opposite to the first substrate 110. In the present embodiment, the second substrate 170 is, for example, a color filter array substrate, in which a black matrix layer (not shown), a color filter layer (not shown), and a sensing electrode 180 are disposed thereon. In the present embodiment, the sensing electrode 180 includes a sensing spacer 182 and an electrode layer 184 which covers a surface of the sensing spacer 182. The sensing electrode 180 is disposed corresponding to one of the sensing units 130 on the first substrate 110. The sensing electrode 180 is located above the black matrix layer, for instance. Herein, the sensing electrode 180 and the corresponding sensing unit 130 constitute a sensing structure 105, and a gap G₁ is formed between each sensing electrode 180 and the corresponding sensing unit 130. More specifically, the gap G₁ refers to a distance between a surface of the electrode layer 184 of the sensing electrode 180 and a surface of the electrode layer 136 of the sensing unit 130. When this touch display panel is pressed, the electrode layer 184 of the sensing electrode 180 contacts the electrode layer 136 of the sensing unit 130 on the opposite side, so as to identify the touch position.

In the present embodiment, a main-spacer 190 and a sub-spacer 192 are further disposed on the second substrate 170. The electrode layer 184 extends onto the main-spacer 190 and the sub-spacer 192, for example, and covers the same. Particularly, the main-stacked layer 150 on the first substrate 110 is disposed corresponding to the main-spacer 190. Moreover, the top of the main-spacer 190 contacts with the main-stacked layer 150 to maintain a gap G₂ between the first and the second substrates 110, 170. The sub-stacked layer 152 on the first substrate 110 is disposed corresponding to the sub-spacer 192. The sub-stacked layer 152 does not contact with the sub-spacer 192, and a certain gap is maintained therebetween. Therefore, the main function of the sub-spacer 192 is to support the main-spacer 190. That is, when a force impacts the display panel, the sub-spacer 192 provides a reaction force to maintain the gap G₂ between the first and the second substrates 110, 170. Here, the sensing spacer 182, the main-spacer 190, and the sub-spacer 192 are fabricated using photoresist material, for instance. The electrode layer 184 is fabricated using transparent conductive material such as ITO. It should be noted that the types of the first substrate 110 and the second substrate 170 are not limited in the invention. In other embodiments, for example, the first substrate 110 is a color filter on array substrate or an array on color filter substrate each integrated with a color filter layer. On the other hand, the second substrate 170 is an opposite substrate.

The touch display panel 100 of the present embodiment further includes an alignment layer 194 disposed on the second substrate 170. The alignment layer 194 covers a side surface of the sensing electrode 180 and exposes an upper surface of the sensing electrode 180. Similarly, the alignment layer 194 is fabricated using PI or other suitable alignment materials, for instance, and is fabricated by performing printing process and re-flowing process, for example. In the present embodiment, since the sensing electrode 180 includes an electrode layer 184, the alignment layer 194 thus covers the electrode layer 184 and at least exposes a potion of the electrode layer 184. Accordingly, when the touch display panel 100 is pressed, the electrode layer 184 of the sensing electrode 180 contacts the electrode layer 136 of the sensing unit 130 on the opposite side, such that the touch position is identified.

Generally, in the fabrication of touch panels, the shape and size of sensing patterns affect the thickness distribution of the alignment layer on the sensing patterns. Smaller sensing patterns normally facilitate in reducing the alignment layer remained on the top of the sensing patterns. However, the size of the sensing patterns is restrained by the resolution of the lithography process, and it is thus difficult to enhance the sensibility of the touch panel by manufacturing smaller sensing patterns to control the distribution of the alignment layer. Consequently, the sensor structure of the present embodiment includes main-sensing patterns and sub-sensing patterns with different sizes. When the alignment material is formed onto the first substrate by performing the printing process and the re-flowing process, main-sensing patterns and sub-sensing patterns with different sizes facilitate in distributing the alignment material, such that the thickness of alignment material remained on the main-sensing patterns and the sub-sensing patterns is reduced to expose at least one of the main-sensing patterns and the sub-sensing patterns. In other words, the compensation of the main-sensing patterns and the sub-sensing patterns enhances sensibility of the sensor structure, so that the active force variation for touch sensing of the touch display panel caused by fabrication variation is reduced.

In summary, the sensor structure of the invention includes the main-sensing patterns and the sub-sensing patterns with different sizes, and is adopted in integrated type touch display panels. When the sensor structure is applied in the integrated touch display panel, the main-sensing patterns and the sub-sensing patterns with different sizes facilitate in distributing the alignment material, such that the thickness of alignment material remained on the main-sensing patterns and the sub-sensing patterns is reduced to expose at least one of the main-sensing patterns and the sub-sensing patterns. Through the compensation of the main-sensing patterns and the sub-sensing patterns, the sensibility of the sensor structure is enhanced, so that the active force variation for touch sensing of the touch display panel caused by fabrication variation is reduced.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A touch display panel, comprising:
a first substrate;
a plurality of sensing units disposed on the first substrate, each sensing unit including a main-sensing pattern and at least one sub-sensing pattern, wherein the at least one sub-sensing pattern is electrically connected to the main-sensing pattern and a size of the at least one sub-sensing pattern is smaller than a size of the main-sensing pattern;
a second substrate; and
a plurality of sensing electrodes disposed on the second substrate, and each sensing electrode disposed corresponding to one of the sensing units on the first substrate.

2. The touch display panel as claimed in claim 1, wherein a thickness of the at least one sub-sensing pattern substantially equals to a thickness of the main-sensing pattern.

3. The touch display panel as claimed in claim 1, wherein a width of a short side of the at least one sub-sensing pattern is about 0.1 to about 1.0 micrometer (μm) smaller than a width of a short side of the main-sensing pattern.

4. The touch display panel as claimed in claim 1, wherein a distance between the at least one sub-sensing pattern and the main-sensing pattern ranges from about 2.0 to about 20 μm.

5. The touch display panel as claimed in claim 1, further comprising an alignment layer disposed on the first substrate to cover the sensing units, wherein the alignment layer exposes at least one of the main-sensing pattern and the at least one sub-sensing pattern of each sensing unit.

6. The touch display panel as claimed in claim 1, wherein each sensing unit further comprises an electrode layer covering on the main-sensing pattern and the at least one sub-sensing pattern.

7. The touch display panel as claimed in claim 1, wherein each sensing electrode on the second substrate comprises a sensing spacer and an electrode layer covering a surface of the sensing spacer.

8. The touch display panel as claimed in claim 1, further comprising an alignment layer disposed on the second substrate to cover side surfaces of the sensing electrodes and to expose upper surfaces of the sensing electrodes.

9. The touch display panel as claimed in claim 1, further comprises:
a plurality of main-spacers disposed on the second substrate; and
a plurality of sub-spacers disposed on the second substrate, wherein a distance is formed between the first substrate and the second substrate.

10. The touch display panel as claimed in claim 9, further comprises:
a plurality of main-stacked layers disposed on the first substrate and corresponding to the main-spacers; and
a plurality of sub-stacked layers disposed on the first substrate and corresponding to the sub-spacers.

11. The touch display panel as claimed in claim 1, further comprising a display medium disposed between the first substrate and the second substrate.

12. A sensor structure, comprising:
a plurality of main-sensing patterns;
a plurality of sub-sensing patterns, wherein at least one of the sub-sensing patterns is electrically connected to at least one of the main-sensing patterns, and a size of the at least one sub-sensing pattern is smaller than that of the at least one main-sensing pattern; and
a sensing electrode disposed opposite to the main-sensing patterns and the sub-sensing patterns.

13. The sensor structure as claimed in claim 12, wherein a thickness of the at least one sub-sensing pattern substantially equals to that of the at least one main-sensing pattern.

14. The sensor structure as claimed in claim 12, wherein a width of a short side of the at least one sub-sensing pattern is about 0.1 to about 1.0 μm smaller than that of a short side of the at least one main-sensing pattern.

15. The sensor structure as claimed in claim 12, wherein a distance between the at least one sub-sensing pattern and the at least one main-sensing pattern ranges from about 2.0 to about 20 μm.

16. The sensor structure as claimed in claim 12, further comprising an alignment layer covering the main-sensing patterns and the sub-sensing patterns, and the alignment layer exposing at least one of the main-sensing patterns and the sub-sensing patterns.

17. The sensor structure as claimed in claim 12, further comprising an alignment layer covering a side surface of the sensing electrode and exposing an upper surface of the sensing electrode.
